(19) United States
(12) Patent Application Publication
(10) Pub. No.: US 2006/0203899 A1
(43) Pub. Date: Sep. 14, 2006

(54) Method of equalising a channel and apparatus therefor

(76) Inventor: David Martin Gee, Manningtree (GB)

Correspondence Address: PERMAN & GREEN, 425 POST ROAD, FAIRFIELD, CT, 06824, US

(21) Appl. No.: 11/344,337

(22) Filed: Jan. 31, 2006

(30) Foreign Application Priority Data
Feb. 3, 2005 (GB) 0502186.0

(51) Int. Cl. H03H 7/30

(52) U.S. Cl. 375/232

(57) ABSTRACT

In the field of optical communications, a number of techniques are known for channel equalisation. However, these techniques are, for various different technical and/or economic reasons, unsuitable for application in relation to optical communications at a data rate of 10 Gbps. Consequently, the present invention provides a dithered linear search algorithm adapted to change tap weights (45, 75) of a filter (15) in accordance with a heuristic tap modification scheme.

The present invention relates to a method of equalising a channel of the type, for example that adapts filter tap coefficients. The channel is, for example, a channel in a communications network, such as an optical communications network. The present invention also relates to an apparatus for equalising a communications channel.

In the field of optical equalisation, it is currently desirable to develop Integrated Circuits (ICs) to extend electrically the optical transmission distance achievable at 10 Gb/s over multi-mode fibre. A short-term goal is to achieve lossless data transmission at 10 Gb/s over 300 metres of multi-mode grade fibre. Currently, an equalizer architecture sufficiently robust to achieve the 300 metres of lossless transmission consistently is not available. Work is thus underway in a number of companies to improve the equalizer algorithms and their implementations in silicon and software to achieve this 300 metre goal.

Many of the traditional adaptation methods use training sequences to guide an adaptation algorithm, but a standard being developped by the Institute of Electrical and Electronic Engineers (IEEE) does not support such training sequences. Hence, a so-called “blind” equaliser is required that can lock-on to a “typical” random data transmission.

A well-known blind adaptation method employs a Least Mean Squares (LMS) algorithm, but is not very efficient to implement at 10 Gb/s, because it requires access to internal values within a filter being adapted (typically, node voltages). In the case of a typical Finite Impulse Response Filter (FIR), the LMS method requires all signal values stored in delay elements of the filter. Similarly, with a Decision Feedback Equaliser (DFE) LMS method, direct access to values stored in the delay elements is also required.

Current generation 10 Gb/s equaliser filters use analogue delay lines and analogue storage of the values. To access the analogue delay lines and process them to derive LMS correlation information requires a substantial quantity of additional analogue circuitry operating at 10 Gb/s. This circuitry would consume a substantial quantity of additional power, place additional loading on the filter's internal nodes and force these nodes to exist physically, which prevents certain filter mathematical transformations being made, and thus constrains the filter design. It also requires fairly precise time alignment to be maintained between all points in the filter, so that the correct time aligned quantities are correlated.

Another equalization technique treats an adaptive filter as a “back box”. The “black box” has a number of input ports, and typically one output port. A change or changes are made to input port signals and a resulting effect is observed at the output port. Such systems generally require much less circuitry running at 10 Gb/s and place no constraints on the contents of the “black box”. The system does, however, tend to be slower to adapt to a channel due to the adaptation algorithm only being able to observe the filter output and not the values within the filter and, therefore, has less information to guide it to a correct solution.

One variant of the “black box” method is a Dithered Linear Search (DLS) algorithm. The DLS algorithm makes perturbations to filter taps and correlates the perturbations with a shape of an output signal from the filter. These correlations are integrated over a period of time to derive a gradient vector, which is then used to calculate a magnitude and direction in which to vary the filter taps. However, if the resulting vector is applied with insufficient damping, i.e. too little attenuation or too steep an integration time, the algorithm goes into oscillation and does not converge on a solution. Conversely, if the vector is attenuated too much, the time taken for the filter to converge on the solution can be unacceptably slow in some circumstances. Additionally, both the perturbations and channel data traffic are required to be balanced random data, i.e. an equal number of 1's and 0's, and no DC offsets.

Furthermore, the DLS algorithm and other “black box” methods require an “eye quality” or other “link quality” measurement to be taken on the output of the filter. One conceptually simple approach would be to use an oscilloscope to plot an eye diagram for the output of the filter and visually measure the positive or negative eye mask margin. However, although an IC could be designed to do this, it is not as practical or efficient as some other known methods. Another, more practical approach, is to examine the height and width of an eye using an auxiliary Clock and Data Recovery (CDR) circuit, running in parallel with the IC's main receiver CDR. The auxiliary CDR would have a variable time and voltage offset so as to move a sample point of the auxiliary CDR in relation to the main receiver CDR. By varying the offsets and correlating the two data patterns, it is possible to trace out the size and shape of the eye, and indeed large parts of the CDRs may be common.

However, the most common approach to measuring the eye quality is using a Mean Squared Error (MSE) function, which compares a linear output from a filter with a quantised version of the output of the filter and integrates the error between the two, either squared or possibly rectified. This is simpler to do within an IC as it can be done without knowledge of the recovered clock, i.e. no auxiliary CDR is required, and a valid readout even when the eye is visibly closed is obtained; this is an important feature for initial lock-on to the channel.

One weakness of the DLS algorithm used in conjunction with the MSE function is that the dithers can generate a lot of noise, because all the taps of the filter are simultaneously moved by +/−1 Least Significant Bit (LSB). For example, a 9-tap Finite Impulse Response (FIR) and 4-tap DFE filter has a total of 13 LSBs worth of eye closure noise. Occasionally, a dither vector is randomly produced where all 13 changes all add up linearly, i.e. in one direction, to generate a peak eye closure. This can be very severe if the filter taps are of insufficient precision and causes what is known as transient peak eye closure that can lead to poor noise immunity and even to errors on an otherwise noiseless link.

Additionally, difficulties arise in relation to normalisation of the DLS algorithm in the light of limited arithmetic precision. In this respect, a typical DSP algorithm re-normalises a maximum tap value, known as a cursor tap, to “+1” and the remaining taps are fractions of the cursor tap. However, it is not always clear how to make best use of the finite available tap range to keep the cursor tap constant, without either creating tap overflows or complex quantised divisions; quantised division creates a significant quantity of noise with respect to a digital algorithm and is also costly to implement.

In addition to the LMS type algorithms and the output observation based “black box” algorithms described above, another class of “black box” algorithm also exists; instead of observing the output of the black box, the algorithm observes the input to the back box. By directly analysing the output of the transmission channel, and knowing the statistics of the data running over a given link, it is possible to build up a mathematical model of an equaliser characteristic required. The characteristic is then created by setting the equaliser taps into an open loop mode. The drawback of the algorithm is in the reliance of the algorithm on exact knowledge of the behaviour of the black box as a mathematical element; this is not easily accomplished in analogue circuitry that needs to operate at 10 Gb/s. This approach therefore suffers from the limitation of an inability to observe “non-linearities” and so cannot correct for these non-linearities in the absence of accurate pre-calibration. Rather, the algorithm relies upon an accurate filter function, something common in the field of digital DSP, but challenging to achieve in the analogue domain, and particularly so at speeds of 10 Gb/s.

As alluded to above, filter imperfections can impair operation of the above-described algorithms, such imperfections including: signal attenuation in analogue delay lines; bandwidth constrictions anywhere in a given system; non-flat delay cell group delay, resulting in not all frequencies being uniformly delayed within the filter delay stages; non-linearities in the channel or receiver, creating cross modulation products, potentially alter the DC zero crossing point, the non-linearities being of optical or electrical origin, for example as a result of receiver circuit linearity, laser driver linearity, laser linearity and/or optical amplifier linearity.

A method according to a first aspect of the present invention makes use of the fact that a solution space is typically very restricted in realistic 10 Gb/s adaptive filters, and thus the degrees of freedom are much less than they first appear. Consequently, heuristic changes can be made to the taps of a DLS equaliser algorithm. Indeed, the method is a bridge between a heuristic approach and a DLS algorithm and can be expressed as a dithered linear search algorithm adapted to change tap coefficients of a filter in accordance with a heuristic tap modification scheme.

The algorithm may use improvements immediately (unlike the DLS algorithm) but may also retain knowledge of rejected (as well as accepted) trials, as would be the case with DLS integration.

According to a second aspect of the present invention, there is provided a method of equalising a channel by adapting tap coefficients of an equaliser apparatus, the method comprising the steps of: setting the tap coefficients to a seed solution, the seed solution being a minimum iteration distance from a set of plausible solutions; making a heuristic change to the tap coefficients of a filter; measuring a link quality of an output signal associated with the heuristic change to the tap coefficients.

The heuristic algorithm may be an approximation algorithm.

The method may further comprise the step of: generating cumulative-type vector information by integrating data corresponding to the heuristic change to the tap coefficients. The cumulative-type vector information may be DLS-type vector information. The data corresponding to the heuristic change to the tap coefficients may be correlated the output signal.

The method may further comprise the step of: applying a correction factor to a gradient of the cumulative-type vector information.

The cumulative-type vector information may be applied to the tap coefficients as an occasional change to the tap coefficients when a predetermined criterion has been satisfied in relation to generation of the cumulative-type vector.

The method may further comprise the step of: retaining the heuristic change in response to the link quality having improved.

The method may further comprise the step of: making another similar heuristic change. Indeed, the method may further comprise the step of: repeating the heuristic change to the tap coefficients.

The method may further comprise the steps of: discarding the heuristic change in response to the link quality not having improved; and making a different heuristic change to the tap coefficients.

The different heuristic change may be an opposite change to the heuristic change made to the tap coefficients.

The method may further comprise the steps of: using a Minimum Square Error (MSE) function to measure the link quality.

The method may further comprise the step of: changing a quantiser gain for the MSE function in response to tap coefficients over- or under-flowing.

The method may further comprise the step of: varying each of the tap coefficients in turn once the filter has substantially converged to the channel.

The heuristic change comprises the step of: heuristically varying up to a maximum of a predetermined number of the tap coefficients.

The method may further comprise the step of: limiting the quantum of change to any given tap coefficient to a predetermined number of Least Significant Bits (LSB). The predetermined number of LSBs is one.

The method may further comprise the step of: randomly discarding a predetermined proportion of changes to be made.

The method may further comprise the step of: prohibiting changes to the tap coefficients that result in overflow or wrap-around of one or more of the taps.

The taps may comprise a cursor tap and the method may further comprise the steps of: identifying the cursor taps and whether the value of a tap coefficient corresponding to the cursor tap exceeds a maximum or falls below a minimum predetermined value; varying a gain in relation to the link quality measure in response the value of the tap coefficient corresponding to the cursor tap exceeding the maximum or falling below the minimum predetermined value.

According to a third aspect of the present invention, there is provided a computer program element comprising computer program code means to make a computer execute the method as set forth above in relation to the first or second aspects of the invention.

The computer program element may be embodied on a computer readable medium.

According to a fourth aspect of the present invention, there is provided an apparatus for equalising a communications channel, the apparatus comprising: a filter for receiving a bit stream, the filter comprising taps; and a processing resource arranged to set, when in use, the coefficients of the taps to a seed solution, the seed solution being a minimum iteration distance from a set of plausible solutions; and make a heuristic change to the tap coefficients of a filter; wherein the processing resource is further arranged to measure, when in use, a link quality associated with an output signal resulting from the heuristic change to the tap coefficients.

According to a fifth aspect of the present invention, there is provided an adaptive equaliser apparatus comprising the apparatus for equalising a communications channel as set forth above in relation to the fourth aspect of the invention.

According to a sixth aspect of the present invention, there is provided an optical receiver comprising the apparatus for equalising a communications channel as set forth above in relation to the fourth aspect of the invention.

In one purely exemplary embodiment of the above-mentioned heuristic approach, filter taps formed from 6 bit digital to analogue converters can be used in an equaliser. Each tap can therefore only take up to 64 values, and typically only 63 to preserve symmetry, these being “+31” through to “−31”. Consequently, a filter comprising 9 Finite Impulse Response (FIR) taps still corresponds to a large solution space (63⁹ possible solutions). The tap having a largest magnitude of all the taps, known as a “cursor” tap, which put simply defines a pulse time delay through the filter, is constrained to a fixed location, for example a the centre tap of the FIR filter. Due to the mathematics underlying FIR equaliser filters, the taps will decay away from the cursor tap, and typically as a decaying power series. Therefore, for all realistic channels, the outer taps will be of a small magnitude relative to the cursor tap. Thus, in a situation where the correct value for the centre cursor tap is “+26”, the outermost taps are expected to be in the range of “+3” to “−3” (10% or less of the cursor tap). Similarly taps closer in to the cursor tap are generally less than say 50% of the cursor tap. Thus, it can be seen that the FIR solution space falls from 63⁹ to a substantially smaller subset of plausible tap weight distributions.

One key weakness of the DLS algorithm stated above is that the random dithers generate a lot of noise, as all taps are moved at once by +/−1 LSB. The method may reduce dither noise by one or both of the following techniques. Firstly, when the filter may be deemed to have converged to the channel, because the residual MSE error may be low, the filter may be able to reduce to varying just a single tap at a time by 1 LSB. This is mathematically the lowest dither possible in a fully quantised system. Single tap, low noise dither is referred to herein to as “stepping”. Unlike the generally random tap dither selection, the algorithm systematically may step through each tap in turn in one of a set of prescribed sequences. A second way the dither noise may be reduced, is that during convergence, the basic heuristic “trial and error” approach may be performed with as few or as many taps varied as is considered appropriate.

The algorithm may generate a dither with random sign (+ or −) and/or random amplitude (0 or 1). Only those few random dithers with low enough energy may be used, whereas the rest of the dithers may be discarded immediately and a new random replacement dither may be obtained. Typically, a normal PRBS (Pseudo-Random Binary Sequence) may not be sufficient to generate such random data, since rejection of some dithers as being too high energy introduces correlation into the PRBS selections used; each PRBS word is related to the last by a simple shift. Therefore, a reverse word XOR may be used on data from a longer PRBS pattern, to reduce correlation between successive PRBS words. For additional safety, there an optional watchdog feature may be provided. In this respect, if sequences of random dithers continually fail the energy test, eventually, for example 1024 dither fails, the watchdog may cease to attempt to find a low-noise dither and may, instead, use a “noisy” dither regardless of energy rather than potentially permanently hang the algorithm.

The low energy dithers may upset the magnitude of the subsequent DLS integration. Consequently, the DLS gradient may require the application of a correction factor thereto in order to take account of the sparse nature of the applied dither vector.

In the event that the DLS integration becomes further unbalanced as not only is the dither sign random, but the amplitude can be on or of, this unbalance may be corrected by trying both “dither” and its inverse vector “−dither”, thereby the dither pairs may correlate to a zero mean DC value. Therefore, it is possible to achieve lower levels of energy dither than that used in the conventional DLS method. The dither noise power may be exchanged for a longer sequence of lower energy dithers to obtain the same information resolved to the same accuracy. The DLS dithers may be spread out in time to reduce their amplitude.

The DLS vector may be created by integrating the dither results. The DLS vector may be limited in energy. This is important, as due to the random nature of the dithers, the DLS vector has a random noise superimposed on it, which will also create eye closure. The DLS vector may, therefore, be limited in two ways: the maximum move of any one tap may be limited to 1 LSB and/or the number of taps moved may be limited.

At first sight, limiting the vector component amplitudes to 1 LSB may appear to discard a great deal of information. However, with only 6 bit taps, a 1 LSB change is quite a large amount, and still more than one really wants for optimum DLS stability. The 1 LSB move may be decided by examining the vector components and a move may only be made if the magnitude of that component is above a user defined threshold. So, “small vector components” are discarded.

To emulate the effect of more bits of resolution, a proportion, for example 0%, 50% or 75%, of otherwise valid 1 LSB vector component moves may be randomly discarded. This gives an equivalent effective resolution of 1 LSB, 0.5 LSBs or 0.25 LSBs. A cap may optionally be placed on the total number of moves, to stop the random occurrence of all moves being accepted—in this case the taps may be updated until a ceiling is reached and the higher taps in array storage are left unchanged. Such random discards, of otherwise good information, at first sight can result in a DLS vector move very different from the wanted direction. However, the DLS vector is already noisy due to the near random nature of the dithers as well as the data pattern dependency in the correlation. Therefore, it may be viewed as just another low energy trial and error dither, but one that the algorithm may be forced to accept even if it is worse.

The DLS algorithm overlay is of particular use as it helps the algorithm over those few occasions when it is otherwise stuck, and cannot make progress without a random nudge (as nowhere may appear to be “downhill”).

Dithers may be prohibited that would cause tap overflow and wrap-round, even where this may unbalance the DLS integration. As such potential overloads are ensured to be rare events, it does not noticeably degrade the usefulness of the DLS vector.

When the algorithm identifies that the biggest tap (the cursor tap) is too large or too small the gain of the MSE function may be incremented or decremented. This gain may drive the goal for the taps up or down, and may automatically handle the tap normalisations, whilst making the minimum delta change to any one tap (as the taps themselves may never be rescaled, just the MSE target goal may be rescaled). The rate of gain change may be set via a digital timer to ensure this feedback loop does not oscillate.

It is thus possible to provide a method and apparatus for equalising a channel comprising a black box type algorithm having a DLS overlay capable of operating with limited precision arithmetic as compared with a high-quality DLS algorithm, thereby placing less processing strain on the programmable analogue filters. Additionally, it is also guaranteed not to oscillate due to almost all aspects of the algorithm being feed-forward, rather than feedback, provided that the DLS overlay is not made so aggressive as to cause DLS oscillation to sets in. Further, the algorithm is sufficiently fast to support the current 300 m applications, whilst requiring much less analogue circuitry and power than existing LMS type solutions. The algorithm is a mixture of a heuristic approach and Dithered Linear Search. It has been shown to work well in situations where the taps are quantised to limited precision (in this case 6 bit DACs). It substantially reduces the noise inherent in limited precision Dithered Linear Search algorithms. As such, it facilitates a low power high performance 10 Gb/s equaliser. This mixture of heuristic and integration can be applied more widely particularly to other limited precision systems.

At least one embodiment of the invention will now be described, by way of example only, with reference to the accompanying drawings, in which:

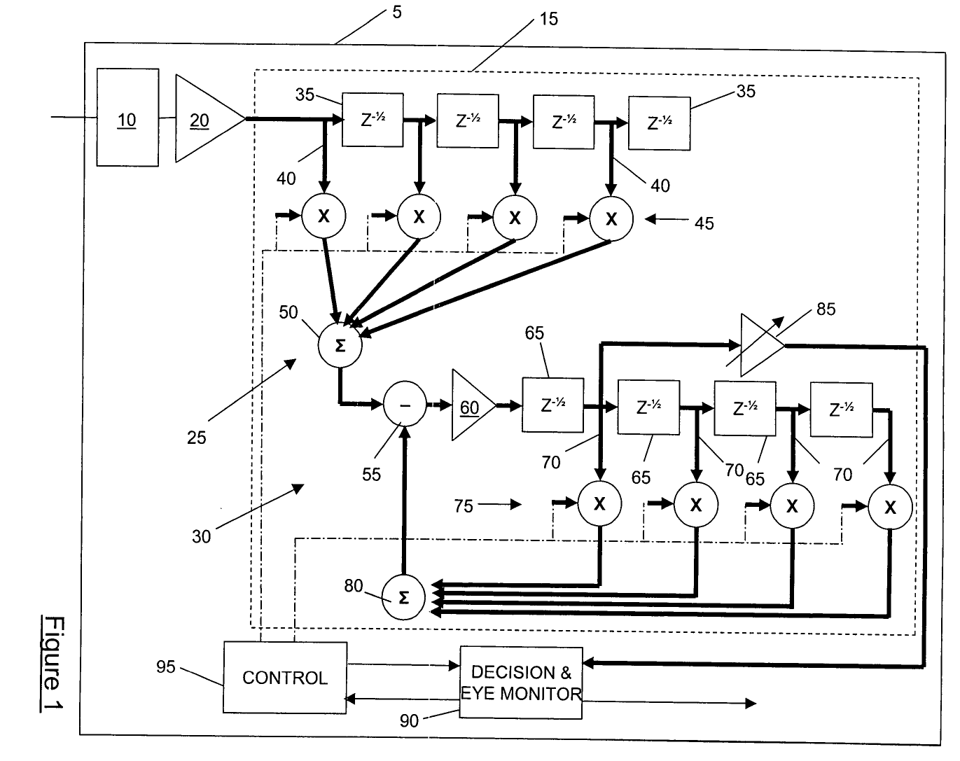

FIG. 1 is a schematic diagram of an equaliser apparatus;

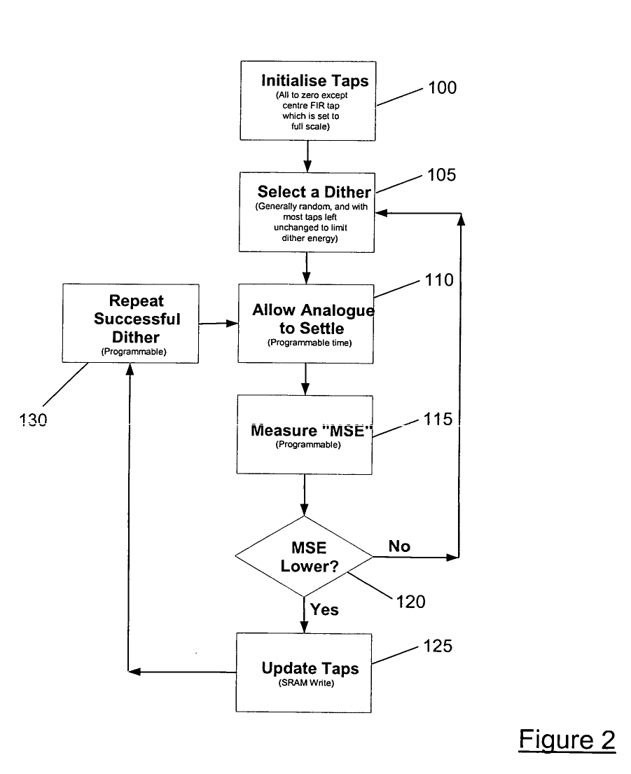

FIG. 2 is a flow diagram of a basic adaptation loop;

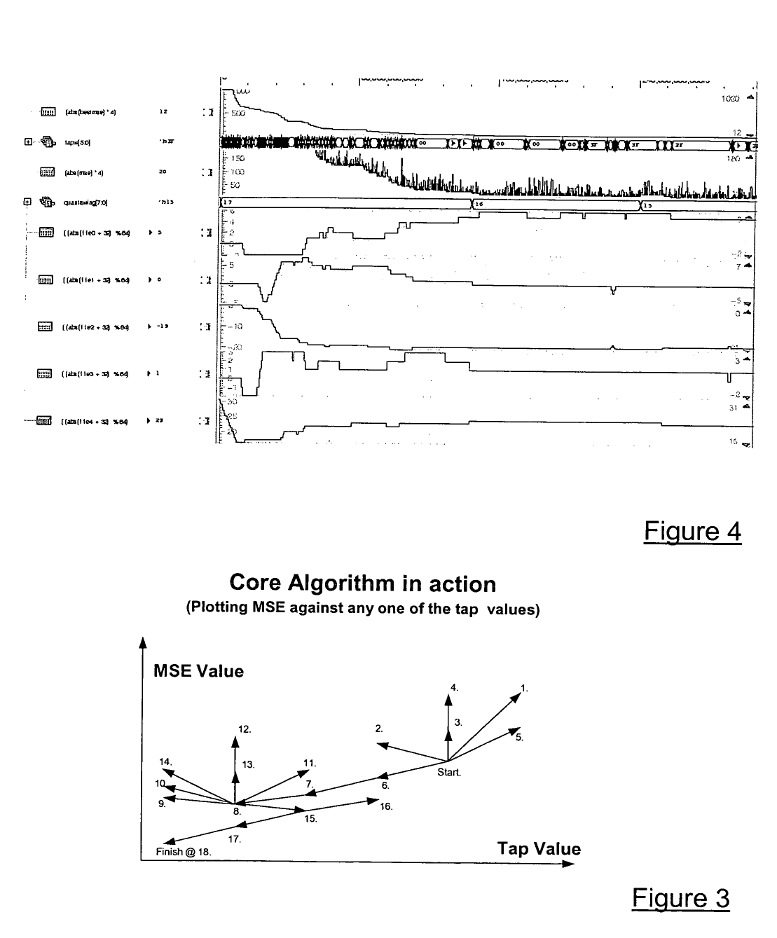

FIG. 3 is a schematic diagram of the core algorithm in action, hunting for an improvement and finding three in relatively quick succession;

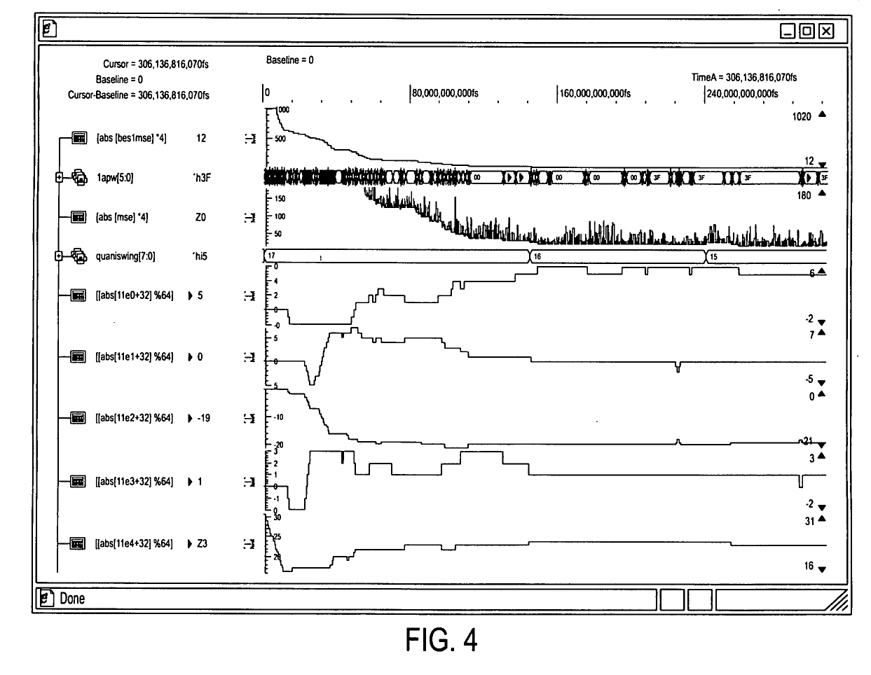

FIG. 4 is a captured screen display of a typical output, showing an equalisation algorithm locking on to a channel;

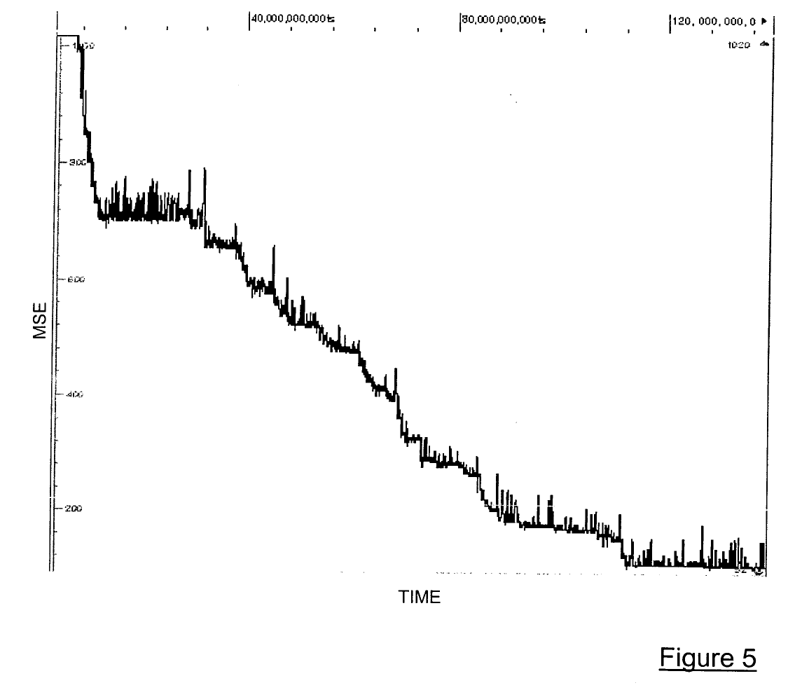

FIG. 5 is a captured screen shot of a subsequent plot of how a typical MSE falls as the algorithm converges;

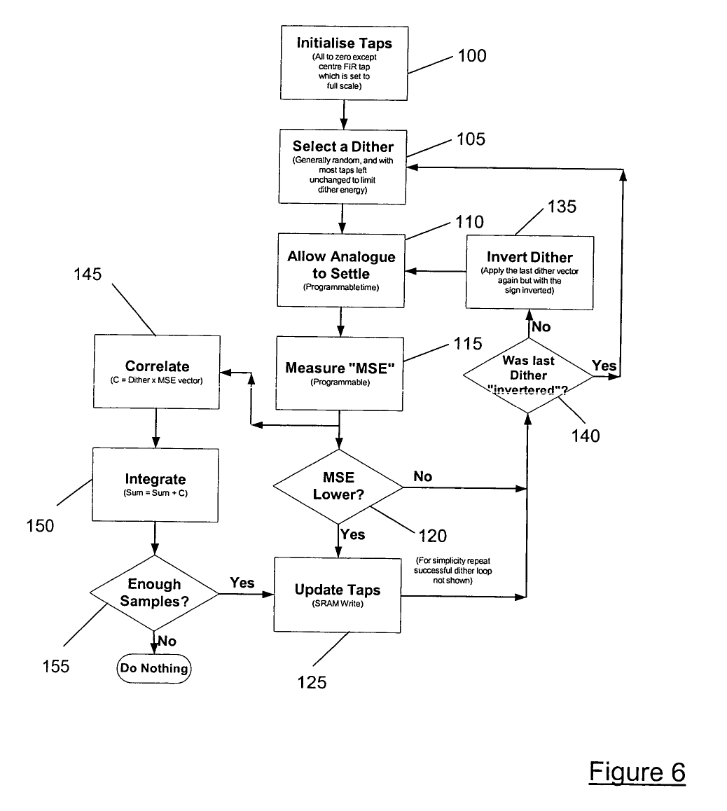

FIG. 6 is a flow diagram of a DLS loop that is laid over the heuristic loop of FIG. 2;

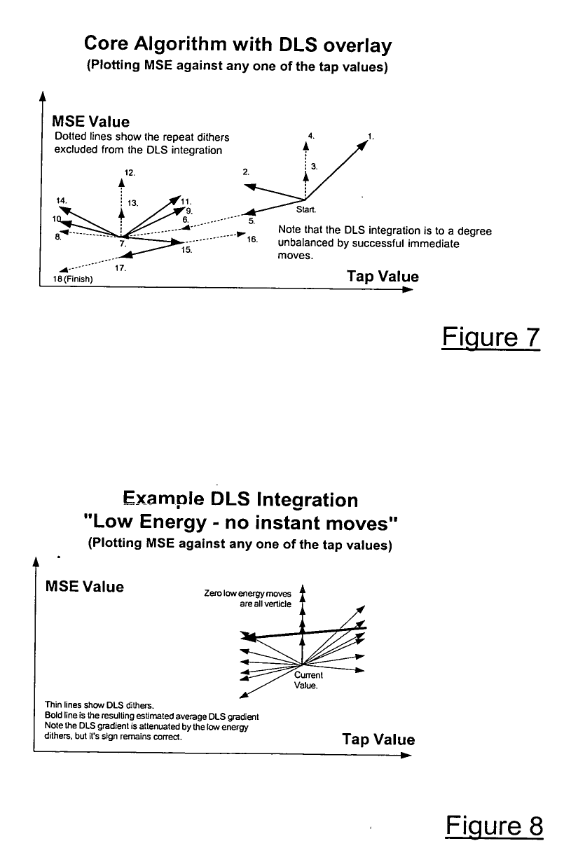

FIG. 7 is a schematic diagram of the DLS loop being applied over the basic heuristic algorithm of FIG. 2;

FIG. 8 is a schematic diagram of the impact of low energy dither on DLS integration;

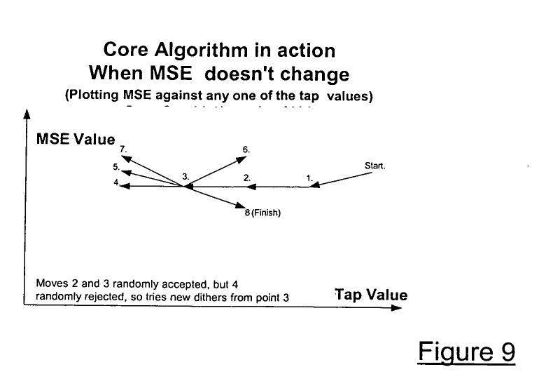

FIG. 9 is a schematic diagram of an example of the algorithm performing a random “walk” when the heuristic changes do not make a useful difference to eye quality;

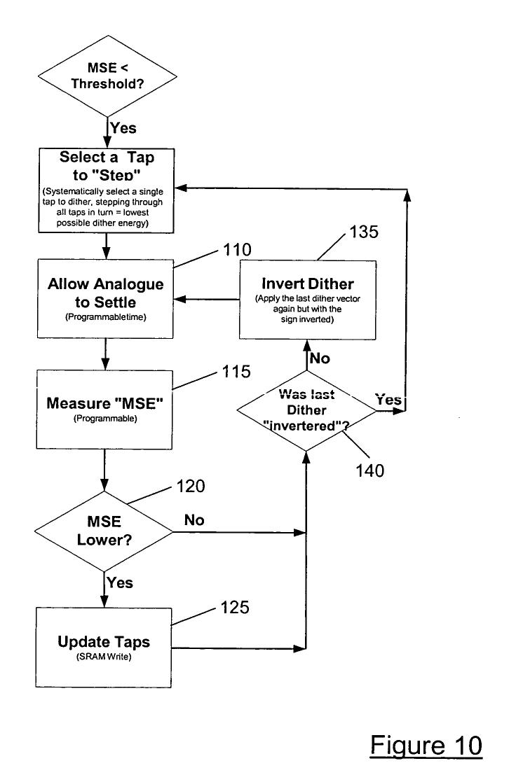

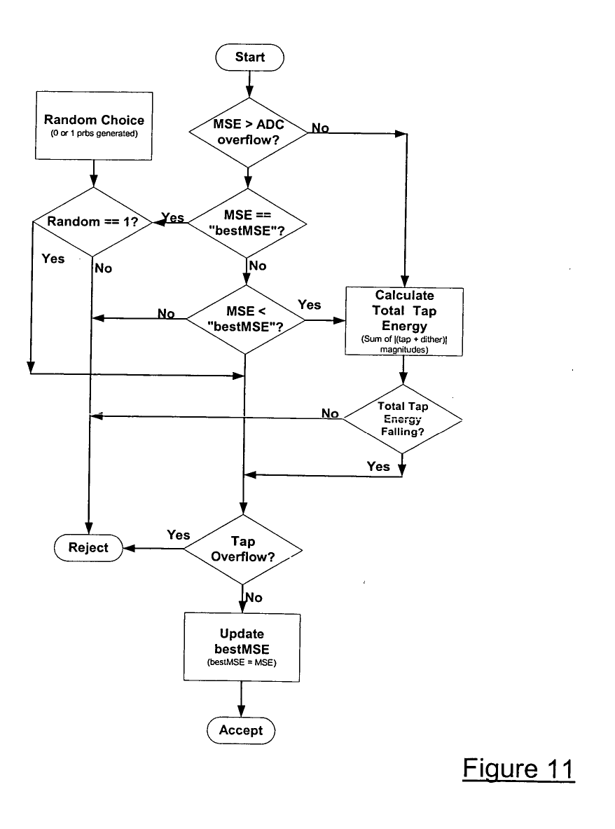

FIG. 10 is a flow diagram of an overview of a converged loop algorithm;

FIG. 11 is a flow diagram of acceptance and rejection of heuristic changes;

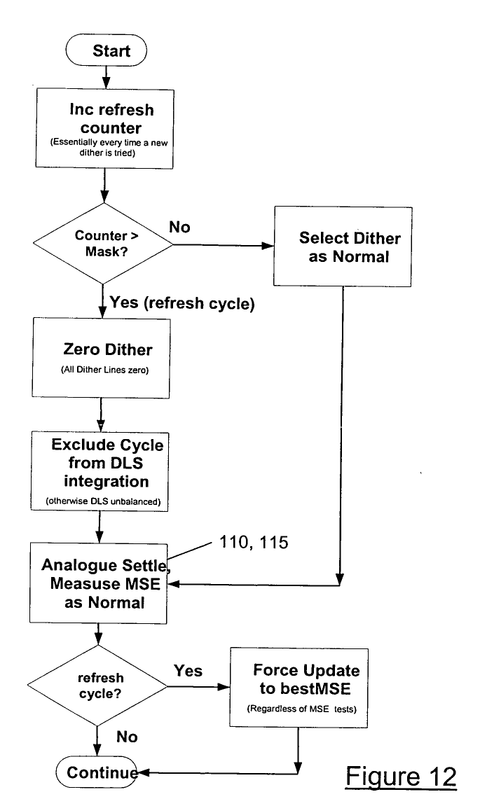

FIG. 12 is a flow diagram of a loop for tracking a time varying channel using a bestMSE refresh;

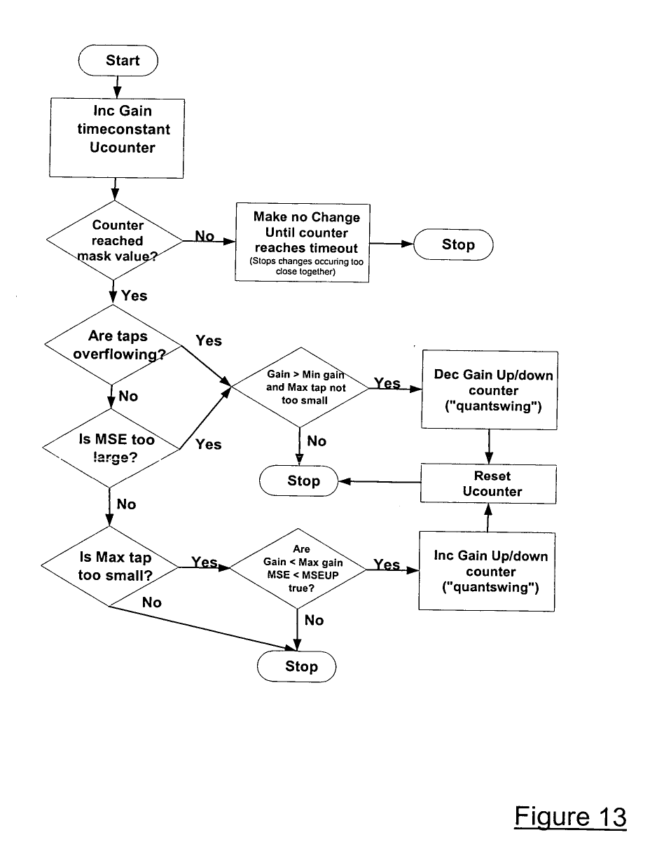

FIG. 13 is a flow diagram of an MSE eye gain control loop;

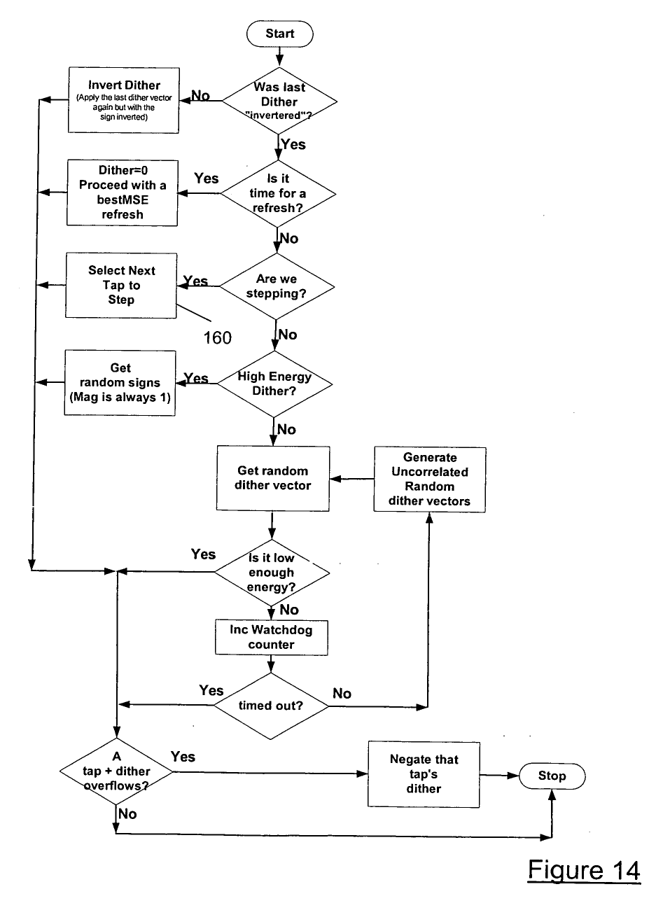

FIG. 14 is a flow diagram of selection of a heuristic change, or dither vector;

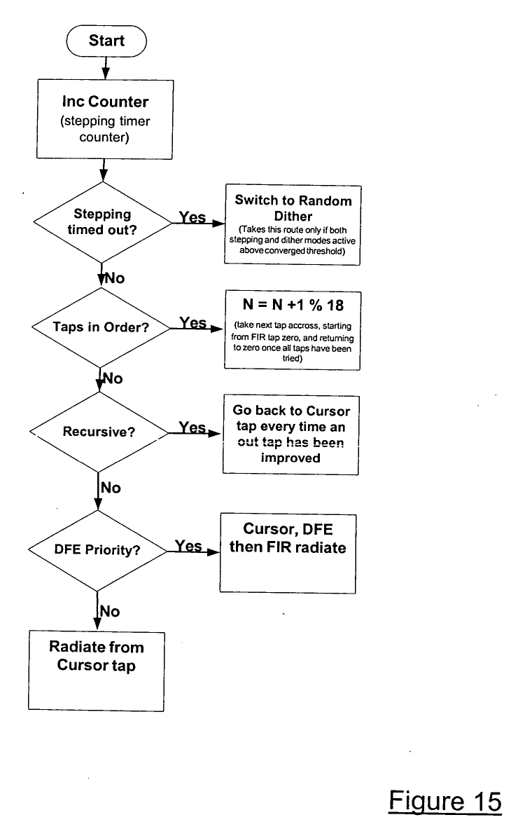

FIG. 15 is a flow diagram of step selection modes;

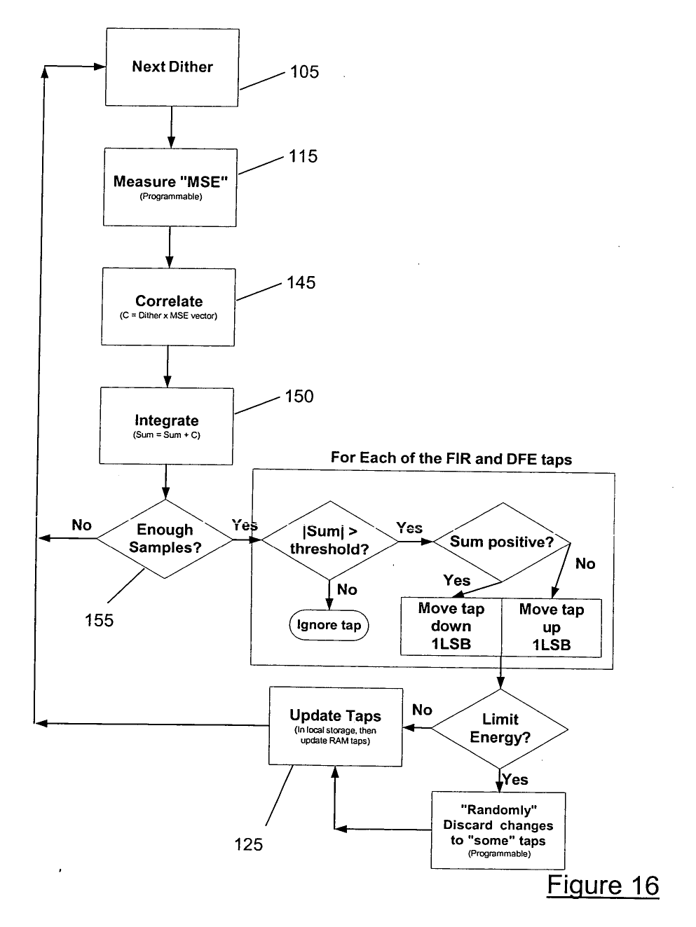

FIG. 16 is a flow diagram of an algorithm that makes 1 LSB DLS moves; and

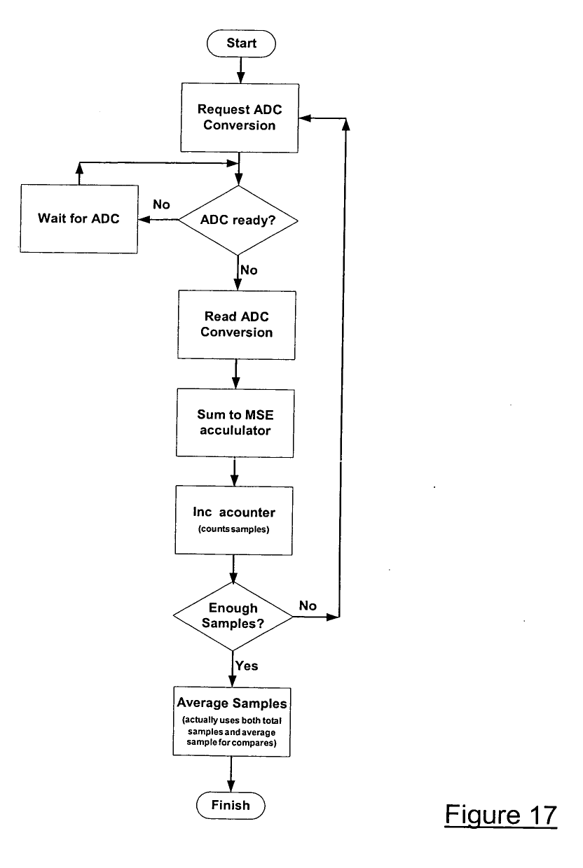

FIG. 17 is a flow diagram of an MSE measurement function.

Throughout the following description identical reference numerals will be used to identify like parts.

Referring to FIG. 1, an optoelectronic receiver 5 comprises a photodiode detector 10 coupled to a filter circuit 15 via an Automatic Gain Control (AGC) amplifier 20. The filter 15 comprises a first Finite Impulse Response (FIR) part 25 and a second Decision Feedback Equaliser (DFE) part 30. The first FIR part 25 comprises a first series of delays 35 and first analogue taps 40, the first taps 40 being weighted 45 and coupled to a first summation unit 50. The first summation unit 50 is coupled to a subtraction unit 55 of the DFE part 30, the DFE part 30 also comprising a quantiser 60 coupled to the subtraction unit 55. The subtraction unit 55 is coupled to a second series of delays 65 and second analogue taps 70, the second taps 70 being weighted 75 and subsequently coupled to a second summation unit 80. The second summation unit 80 is also coupled to the subtraction unit 55.

In this example, the first and second series of delays 35, 65 are Z^{-1/2} delay elements, such delay elements being employed for the sake of convenience of symmetry in relation to transformations of filter architectures. However, the skilled person will appreciate that delay elements of other durations can be employed, for example Z⁻¹ delay elements. Further, due to process tolerances, the Z^{-1/2} delay elements are typically not exact and may be between about Z^{-0.55} and Z^{-0.45}.

An output of the quantiser 60 is coupled by another amplifier unit 85 to a decision and eye/link monitoring unit 90 comprising an MSE function. The decision and eye monitoring unit 90 is coupled to a controller 95 for adapting the first and second tap weights 45, 75. Although not described herein, the another amplifier 85 and the decision and eye monitoring unit 90 can optionally be coupled to a timing recovery unit, but in practice the timing recovery unit, or CDR, is optimally coupled to the output of the quantiser 60, i.e. an input of the another amplifier unit 85, as digital variations in gain can confuse the CDR and lead to the creation of link errors.

In this example, a heuristic equalisation algorithm executed by the controller 95 is implemented as a soft IP block of behavioural Verilog code, which is then compiled onto a target digital cell library and manufactured as part of a silicon chip's hardware.

In operation (FIG. 2), the heuristic algorithm is implemented. Almost every parameter in the heuristic algorithm is tuneable via memory mapped set up registers, but on power-up the values are all initialised (Step 100) to “experimentally best” default values based upon 6 months of simulation. In most cases, these values do not need to be altered, but should any of these values be non-optimal they can be varied via a two-wire interface (not shown in FIG. 1). In most cases, the values have a set legal range that is a subset of an 8-bit word, and values outside the legal range are interpreted and read back as the nearest legal value. In relation to the first and second tap weights 45, 75, the first and second tap weights 45, 75 are therefore set to an initial seed solution. In this example, the tap weights (or coefficients) are set to correspond to a mathematical solution for no channel impairment.

Thereafter, the tap coefficients are dithered (Step 105) in accordance with an initial seed dither suitable for equalising a channel assumed to have no impairment. The algorithm then waits (Step 110) a predetermined period of time in order for the loop, comprising the filter 5, the decision and eye monitoring unit 90 and the controller 95, to respond to the initial setting before obtaining (Step 115) an error signal from the MSE. In the event that the error signal has reduced (Step 120), the tap coefficients are updated (Step 125) to reflect the dither used and the dither is subsequently applied (Step 130) again to the updated tap coefficients. The process of waiting for the loop to settle and deciding if an improvement has occurred (Step 110, 115, 120) are then repeated as well as the step of updating the tap coefficients (Step 125) until the MSE generates an increased error signal with respect to an immediately preceding error signal. It is normally best to repeat successful dithers, as once a “down hill” direction has been located, it is worth following this decent until it goes no further. Once the downward trend starts to reverse or, in some examples, simply ceases, i.e. the error signal increases or ceases to reduce, the dither is varied (Step 105) in accordance with a dither selection scheme as will be described in greater detail later herein.

Referring to FIG. 3, throughout the execution of the algorithm, a number of different dithers are tested. In the present example, 18 dithers are tested and shown as vectors. A change in dither usually results either in an increase or decrease in the error signal (MSE value). Dither 1 and dither 2 are a complementary pair of dithers (the need to test both “+dither” and “−dither” is explained later herein). As can be seen, the two dithers move this tap plotted here in opposite directions. Nevertheless, the MSE rises in both cases, but by varying amounts due to the parabolic local gradient conditions on this and the other taps (from this single pair of dithers, the algorithm has no idea which of the taps had most effect as it just sees the total effect). Further, low energy dithers 3 and 4 do not impact this tap at all, which is why they are vertical.

The first half of the new pair 5 is also rejected, whereas dither 6 makes an improvement, so the dither is applied again for dither 7, dither 8 and dither 9; dither 9 is results in an upward change to the MSE value and so the tap coefficients are set to correspond to the application of the eighth dither to the current tap coefficients. After reaching an MSE value based upon the eighth dither, the algorithm tries more dithers (dithers 6-9 were all the inverse of dither 5). Pair 10 and 11 fails. Pair 12 and 13 again does not apply to this tap. Once again dither 14, the first half of a pair, is rejected, whereas dither 15 is accepted, but repeating 15 to 16 fails to make further improvements. Dither 17 and the repeat of dither 17, dither 18, again make further improvements, i.e. reductions, to the MSE value.

Referring to FIG. 4, moving from top to bottom, the traces relate to: a “bestMSE” best MSE value located to date; a tap bus showing the write activity as the filter tap weight values are updated every time a successful dither is identified (or a DLS vector is applied); an MSE showing the noise on it due to the effects of the dither, i.e. it is “bestMSE”+“eye closure dither”; a “quantswing” gain, a gain applied prior to the MSE and after the quantiser 60 to avoid tap re-normalisation. This is only allowed to vary slowly with time, as this is a feedback loop and can oscillate if the digital time constant is too short. A selection of taps (2's complement numbers) is also shown to illustrate how they vary to converge on the channel; the values displayed are base values and ignore instantaneous tap dither superimposed on top of them.

Referring to FIG. 5, it can be seen that at start-up the MSE is constant at full scale (for an 8 bit ADC) and does not initially vary as the taps are dithered. This is handled via MSE overflow coding set out later herein. However, following a reset, the MSE falls rapidly into a linear range due to the choice seed values set. The initial seed conditions are always all taps and initial dither components zero, except for the cursor tap that is at full scale with the corresponding dither being set to decrement the cursor tap. The result is that the cursor tap is repeatedly decremented until it reaches a correct gain value. Once the cursor tap has reduced until no further immediate improvement is found, the algorithm tries a series of random dithers until it makes another (much smaller) breakthrough. Again, the algorithm hunts until it finds another “stair” down, and so on, resulting in a waveform with a characteristic jagged uni-polar noise superimposed on a staircase with uneven tread sizes.

In another example (FIG. 6), the algorithm of FIG. 2 is modified by providing an averaging function to use historic dither information to generate a tap coefficient change based upon averaged data. In order to understand this function more clearly, FIG. 6 now also shows the dither inversion described above in relation to the previous example.

In this respect, Steps 135 and 140 ensure that a corresponding inverse dither to a given selected (Step 105) dither is applied. In order for the averaging function to operate correctly, the data averaged has to be balanced and so the generation of the inverse dithers forces the generation of balancing data. Consequently, when dithers are not repeated or MSE values not in need of refreshing (described later herein),,an MSE measurement made is used to weight (Step 145) a dither vector currently being applied, the weighted dither vector currently being applied then either being added, subtracted or discarded (Step 150) from each element of a DLS integration vector (depending on the value of the tap dither bit “+1”, “−1” or “0”). Essentially, every other dither is an “invert” (or dither{new}=−dither{old}) in order to balance the DLS integral vector as described above. When enough weighted dither vectors have been collected (Step 155), the tap coefficients are updated with a vector corresponding to a fraction of the DLS integration vector irrespective of the dither currently being applied to the tap coefficients. The application of the DLS integration vector can be seen as providing a “nudge” to the tap coefficient values.

Repeats of successful dithers, i.e. dithers applied and that result in a reduction in the MSE value, are not used to contribute to the calculation of the DLS integration vector. Referring to FIG. 7, some interesting results can be seen. Firstly, as mentioned above, repeat dithers are excluded from the DLS integration, as they would further unbalance the DLS integration vector. In the diagram, the bold lines are the moves included in the DLS integration. As can be seen, the fact that the tap coefficients have been changed as a result of improvements in the MSE value does not invalidate the usefulness of the DLS integration vector.

A random variation such as dithering inherently adds noise to a system. This noise can be reduced by not dithering all tap coefficients at once. In this respect (FIG. 8), it can be seen that statistically many/most of the dithers do not reveal any information about the gradient of a tap coefficient. However, by only dithering a number of the tap coefficients, the estimated gradient of the DLS integration vector is N/M smaller than it should be (where N is the mean number of taps dithered at any one time, which is less than the maximum allowed energy as randomly some will be smaller than necessary, and M is the total number of taps), i.e. the MSE change achieved is attenuated. Therefore, knowing the energy threshold set, i.e. the system noise constraints, and the nature of the random numbers used, a correction factor can be established. Published DLS does not allow zero dithers, because to do so would waste time and increase the error bars on the estimated gradient. However, here, where noise is a primary concern, and DLS is only an overlay to a heuristic search method, a trade off exists between noise generated by dither vectors applied and the gradient of the DLS integration vector.

Thus far, it has been assumed that the MSE rises or falls as a result of dithers. However, this is often not the case and particularly common with a square-law MSE error signal, as close to convergence the squared error varies far more slowly than for larger errors and the MSE hardly moves between dithers. In the special case of MSE unchanged, the decision to use (Step 120) the dither vector is a random choice. However, the decision to accept or reject must not be correlated with the original dither. Therefore, to avoid correlations, the decision to accept or reject is based on a different PRBS random sequence generator, from that used to create the original dither.

Referring to FIG. 9, the algorithm starts with a successful downhill dither (second half of a dither pair in this case) and proceeds to repeat it, but with no further improvement. However, it does not discard the repeat dither 2, but randomly chooses to accept it and so repeats the same dither a third time (dither 3). This is also randomly accepted and the algorithm then proceeds to try dither 4. However, dither 4 is randomly rejected, which terminates that dither repeat, and so the algorithm looks for a new dither. The dither pair 5 and 6 is both worse, and so is vector 7, but the inverse of vector 7, dither 8 again shows an improvement.

When the equaliser has adapted the filter to the channel (convergence), the algorithm is switched over to a single-step mode (FIG. 10), the switching point being defined by a predetermined user programmable convergence threshold (preset on power-up to a sensible default value for realistic channels). Once below this threshold, the algorithm no longer performs Steps 145, 150 and 155 to generate the DLS integration vector, since a solution is deemed to have been found; further application of the DLS integration vector adds noise and the system is trying to minimise noise. The heuristic algorithm degenerates to cycling systematically through tap after tap varying one tap weight at a time looking for an MSE reduction. The converged threshold can be set quite high as the systematic stepping will continue to make some improvements. However, it is generally best not to set the threshold very high, because high energy dithering provides many more degrees of freedom than low energy (single-step) dithering. For example, high energy dithering allows switching of energy between the FIR and DFE in a single dither, something not possible with single-stepping. If the converged threshold is set so low that stepping is never enabled, the main low energy heuristic dithering and DLS algorithm leaves a residual noise in the system. This noise remains even where the channel is time invariant, as the algorithm blindly continues to improve on its current solution.

For completeness, referring to FIG. 11, the “MSE Lower?” test (Step 120) of FIGS. 2, 6 and 10 described above is expanded to show more detail, illustrating handling of MSE overflow and Tap overflow tests. In this respect, the MSE test also takes a number of factors into account to handle cases where either MSE or taps are overflowing.

The above described examples equalise static channels. However, in the case of dynamic channel characteristics, in the absence of any dither, successive MSE reading will vary. This can result in all subsequently calculated MSE values associated with subsequently calculated dither vectors being greater than the MSE value currently stored. In order to overcome this problem and accommodate time varying channels, an additional loop (FIG. 12) is implemented to force a regular refresh of the base case, i.e. the previously stored MSE value for the tap coefficients associated therewith. This refresh is essentially a dither vector of zero.

For completeness, one useful algorithm feature is the ability to scale its tap coefficients to make best use of the tap dynamic range. This scaling prevents tap overflow and avoids digital tap normalisation, with its inherent quantisation noise. Referring to FIG. 13, the algorithm can adjust the another amplifier 85, which is the MSE quantiser's gain control DAC to drive the tap weights to the optimum range, thereby avoiding re-scaling the tap coefficients directly within the filters. Consequently, the “target” eye amplitude set by the MSE is reduced in the event that the tap coefficients are too large. Conversely, the target eye amplitude is increased when the tap coefficients are too low.

Referring to FIG. 14, the dither selection step (Step 105), the invert dither step (Step 135) and the dither inversion decision step (Step 140) of FIGS. 2 and 6 are shown in greater detail. In this example, the generation of dither vectors is an iterative process that generates so-called “dither noise”. Consequently, dither vectors are only communicated to the filter once the iterative process has been completed.

Referring to FIG. 15, a selection of a next tap step (Step 160) is shown in greater detail. As previously described, there are a number of ways of selecting the tap to step. The stepping mode can also be enabled, if required, above the converged threshold and it is possible to have the algorithm execute a predefined mixture of stepping and dither as an alternative convergence procedure. In practice, the stepping values are a fixed subset of the values available during dither, but naturally will occur much more frequently if stepping is explicitly enabled. In this example, the algorithm corresponds to a total of 18 FIR and DFE taps, 9 FIR and 9 DFE where the FIR taps start from the zeroth tap as shown in FIG. 15 in relation to the function “N=N+1% 18”.

Referring to FIG. 16, the process of applying the DLS integration vector is shown in greater detail. For context, Steps 105, 115, 125, 145, 150 and 155 are included. Damping of the DLS integration vector prior to application to the taps is shown, damping being used to ensure convergence on the channel without applying changes to the tap coefficients that will cause “overshooting” of the channel.

Referring to FIG. 17, the step of measuring the MSE (Step 115) of FIGS. 2, 6, 10 and 12 is shown. In this example, greater resolution of the MSE value calculated is achieved, at the expense of update speed, by reading multiple MSE samples from an ADC (not shown) of the MSE and averaging them.

Although the above examples are described in the context of a filter comprising taps having coefficients that can be altered, the skilled person will appreciate that other filter structures having adaptable parameters can be employed, for example, a filter having a network of tunable devices, such as resistors, capacitors and/or inductors; the network can be switchable.

In the above examples, the dither is applied by taking the analogue tap values, applying the dither to the analogue tap values and respectively adding the results to the outputs of multipliers 45, 75, the multipliers being 6-bit DACs herein. This approach results in fewer changes to the DACs and hence faster execution of the algorithm. However, the skilled person should appreciate that, alternatively or additionally, the dither can be applied by altering the tap weights applied to the DACs to enable account to be taken automatically of faults in one or more of the DACs, for example, differential non-linearities, such as missing codes and/or unequally spaced analogue values.”

Alternative embodiments of the invention can be implemented as a computer program product for use with a computer system, the computer program product being, for example, a series of computer instructions stored on a tangible data recording medium, such as a diskette, CD-ROM, ROM, or fixed disk, or embodied in a computer data signal, the signal being transmitted over a tangible medium or a wireless medium, for example, microwave or infrared. The series of computer instructions can constitute all or part of the functionality described above, and can also be stored in any memory device, volatile or non-volatile, such as semiconductor, magnetic, optical or other memory device.

1. A method of equalising a channel by adapting tap coefficients of a filter, the method comprising the steps of:
setting the tap coefficients to a seed solution, the seed solution being a minimum iteration distance from a set of plausible solutions;
making a heuristic change to the tap coefficients; and
measuring a link quality associated with an output signal resulting from the heuristic change to the tap coefficients.

2. A method as claimed in claim 1, further comprising the step of:
generating cumulative-type vector information by integrating data corresponding to the heuristic change to the tap coefficients.

3. A method as claimed in claim 2, wherein the cumulative-type vector information is DLS-type vector information.

4. A method as claimed in claim 2, wherein the data corresponding to the heuristic change to the tap coefficients is correlated the output signal.

5. A method as claimed in claim 2, further comprising the step of:
applying a correction factor to a gradient of the cumulative-type vector information.

6. A method as claimed in claim 1, further comprising the step of:
retaining the heuristic change in response to the link quality having improved.

7. A method as claimed in claim 6, further comprising the step of:
making another similar heuristic change.

8. A method as claimed in claim 6, further comprising the step of:
repeating the heuristic change to the tap coefficients.

9. A method as claimed in claim 1, further comprising the steps of:
discarding the heuristic change in response to the link quality not having improved; and
making a different heuristic change to the tap coefficients.

10. A method as claimed in claim 1, further comprising the step of:
using an Minimum Square Error (MSE) function to measure the link quality.

11. A method as claimed in claim 10, further comprising the step of:
changing a quantiser gain for the MSE function in response to tap coefficients over- or under-flowing.

12. A method as claimed in claim 1, the method further comprising the step of:
varying each of the tap coefficients in turn once the filter has substantially converged to the channel.

13. A method as claimed in claim 1, wherein the heuristic change comprises the step of:
heuristically varying up to a maximum of a predetermined number of the tap coefficients.

14. A method as claimed in claim 1, further comprising the step of:
limiting the quantum of change to any given tap coefficient to a predetermined number of Least Significant Bits (LSB).

15. A method as claimed in claim 14, wherein the predetermined number of LSBs is one.

16. A method as claimed in claim 1, further comprising the step of:
randomly discarding a predetermined proportion of changes to be made.

17. A method as claimed in claim 1, further comprising the step of:
prohibiting changes to the tap coefficients that result in overflow or wrap-around of one or more of the taps.

18. A method as claimed in claim 1, wherein the taps comprise a cursor tap and the method further comprises the steps of:
identifying the cursor taps and whether the value of a tap coefficient corresponding to the cursor tap exceeds a maximum or falls below a minimum predetermined value;
varying a gain in relation to the link quality measure in response the value of the tap coefficient corresponding to the cursor tap exceeding the maximum or falling below the minimum predetermined value.

19. A computer program element comprising computer program code means to make a computer execute the method as claimed in claim 1.

20. A computer program element as claimed in claim 19, embodied on a computer readable medium.

21. An apparatus for equalising a communications channel, the apparatus comprising:
a filter for receiving a bit stream, the filter comprising taps; and
a processing resource arranged to set, when in use, coefficients of the taps to a seed solution, the seed solution being a minimum iteration distance from a set of plausible solutions, and make a heuristic change to the tap coefficients of the filter; wherein the processing resource is further arranged to measure, when in use, a link quality associated with an output signal resulting from the heuristic change to the tap coefficients.

23. An adaptive equaliser apparatus comprising the apparatus for equalising a communications channel as claimed in claim 22.

24. An optical receiver comprising the apparatus for equalising a communications channel as claimed in claim 22.

25. A method of equalising a channel substantially as hereinbefore described with reference to accompanying FIGS. 2 to 17.

26. An apparatus for equalising a communications channel substantially as hereinbefore described with reference to accompanying FIGS. 1 to 17.
